(19) United States
(12) Patent Application Publication
(10) Pub. No.: US 2008/0078571 A1
(43) Pub. Date: Apr. 3, 2008

(54) Device mounting board and semiconductor module

(75) Inventors: Toshikazu Imaoka, Ogaki-City (JP); Tetsuro Sawai, Hashima-shi (JP)

Correspondence Address: FISH & RICHARDSON P.C., P.O. BOX 1022, MINNEAPOLIS, MN, 55440-1022, US

(73) Assignee: SANYO ELECTRIC CO., LTD., Osaka (JP)

(21) Appl. No.: 11/861,712

(22) Filed: Sep. 26, 2007

(30) Foreign Application Priority Data
Sep. 29, 2006 (JP) 2006-266887
Aug. 31, 2007 (JP) 2007-226726

(51) Int. Cl. H05K 1/11

(52) U.S. Cl. 174/262

(57) ABSTRACT

A device mounting board includes: a wiring layer; opposing signal wires formed on respective conductive layers, being arranged in parallel with each other; a pair of pad electrodes formed on the top of the wiring layer; a pair of pad electrodes formed on the bottom of the wiring layer; conductor parts which are formed through insulating layers and establish electrical connection between the top and bottom conductive layers; a circuit device mounted on the top side of the wiring layer; and a pair of signal electrodes formed on this circuit device, being connected to the pair of pad electrodes via conductive members. A line extending from one of the pad electrodes on the top to one of the pad electrodes on the bottom through one signal wire and a line extending from the other pad electrode on the top to the other pad electrode on the bottom through the other signal wire constitute a pair of differential transmission lines of equal lengths.

### CROSS-REFERENCE TO RELATED APPLICATIONS

This application is based upon and claims the benefit of priority from the prior Japanese Patent Applications No. 2006-266887, filed Sep. 29, 2006, and Japanese Patent Application No. 2007-226726, filed Aug. 31, 2007, the entire contents of which are incorporated herein by reference.

### BACKGROUND OF THE INVENTION

1. Field of the Invention

The present invention relates to a device mounting board, and in particular, to a device mounting board having differential transmission lines.

2. Description of the Related Art

The data transmission system presently utilized in circuit units intended for use in electronic equipment has been shifting from conventional single-ended transmission to differential transmission due to the speedup of signal processing rates, transmission rates, and the like. A differential transmission system is one in which two phases of signals, being a positive phase signal and a negative phase signal, are generated from one single signal and transmitted using two signal lines. In this system, the signal lines of the positive phase signal and the negative phase signal are electromagnetically coupled to each other so that the two phases of signal lines have the relationship of paths for a signal current and a return current. In comparison to the conventional single-ended transmission system, when utilizing the differential mode used for high-speed transmission, it is possible to reduce electromagnetic radiation noise.

In recent years, the miniaturization and increase in density of circuit units have also meant that wiring boards constituting the circuit units have smaller areas. The adoption of the differential transmission system, however, requires two signal lines for one signal and thus doubles the signal-related wiring formed on the wiring boards. This creates a problem in that the wiring efficiency on the wiring boards deteriorates in comparison to the conventional single-ended transmission system. One example of an attempt to overcome this problem is provided by a method of differential transmission in which two opposing signal lines are laminated and arranged in parallel with each other.

In such a wiring board, two opposing signal wires (signal lines) are laminated and arranged inside the wiring board in parallel with each other, and are connected to connection pads (electrode pads) formed on the topmost layer of the wiring layer through embedded vias, respectively. Moreover, two integrated circuit chips (circuit devices) are mounted on the topmost layer of the wiring board and connected to each other through such connection pads.

In this instance, when signal lines for transmitting differential signals are adopted in an actual circuit unit (device mounting board), the two transmission paths including the signal lines must have equal lengths in order to ensure electrical equivalency between the positive phase signal and the negative phase signal in the differential pair. According to the foregoing wiring board, however, the two signal lines have embedded vias of different respective line lengths (via depths). This difference impairs the isometric properties of the signal lines, and thereby causes a mismatch in differential impedance. A problem with respect to the generation of reflection noise has therefore resulted, causing the circuit devices on the wiring board to malfunction.

### SUMMARY OF THE INVENTION

The present invention has been achieved in view of the foregoing circumstances. It is thus a general purpose of the present invention to provide a device mounting board of smaller size which has excellent characteristics for transmitting differential signals.

To solve the foregoing problem, a device mounting board according to one embodiment of the present invention includes: a wiring layer having a plurality of conductive layers and insulating layers laminated alternately; a pair of first electrodes formed on one main surface of the wiring layer; opposing signal wires formed on different conductive layers in the wiring layer, being arranged in parallel with each other; a pair of second electrodes formed on the other main surface of the wiring layer; and conductor parts which are formed through the insulating layers and respectively establish electrical connection between the first electrodes and the signal wires and between the signal wires and the second electrodes, wherein a first line extending from one of the first electrodes to one of the second electrodes and a second line extending from the other first electrode to the other second electrode constitute a pair of differential transmission lines of equal lengths.

According to this embodiment, the opposing signal lines can be laminated and arranged inside the wiring layer in parallel with each other so that the two lines through these signal lines between the first electrodes and the second electrodes of the device mounting board constitute a pair of differential transmission lines of equal length. This allows the device mounting board to transmit predetermined signals accurately and operate circuit devices mounted thereon properly. In addition, since the area occupied by the signal wires can be reduced in comparison to the cases where the signal wires are arranged in parallel within an identical plane, it is possible to further miniaturize the device mounting board having such signal wires.

A semiconductor module according to another embodiment of the present invention includes: the device mounting board according to the foregoing configuration; and a circuit device arranged on one of the main surfaces of the wiring layer of the device mounting board, wherein the pair of first electrodes are electrically connected with a pair of signal electrodes of the circuit device, respectively, and the pair of second electrodes function as external lead electrodes for transmitting signals to an exterior location. This makes it possible to transmit predetermined signals from the circuit device mounted on the device mounting board to an exterior location accurately at high speed.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a plan view showing the configuration of a device mounting board and a semiconductor module according to a first embodiment of the present invention;

FIGS. 2A and 2B are sectional views of the device mounting board and the semiconductor module taken along the line X-X and the line Y-Y of FIG. 1;

FIG. 3 is a plan view showing the configuration of a device mounting board and a semiconductor module according to a second embodiment of the present invention;

FIGS. 4A and 4B are sectional views of the device mounting board and the semiconductor module taken along the line X-X and the line Y-Y of FIG. 3;

FIG. 5 is a plan view showing the configuration of a device mounting board and a semiconductor module according to a third embodiment of the present invention;

FIGS. 6A and 6B are sectional views of the device mounting board and the semiconductor module taken along the line X-X and the line Y-Y of FIG. 5;

FIG. 7 is a schematic diagram showing how a semiconductor module is mounted on a motherboard according to a fourth embodiment; and

FIG. 8 is a schematic diagram showing how a semiconductor module is mounted on a motherboard according to a fifth embodiment.

### DETAILED DESCRIPTION OF THE INVENTION

The invention will now be described by reference to the preferred embodiments. This does not intend to limit the scope of the present invention, but to exemplify the invention.

Hereinafter, practical embodiments of the present invention will described with reference to the drawings. It should be appreciated that in any of the drawings, identical components will be designated by like reference numerals. Description thereof will be omitted as appropriate.

### First Embodiment

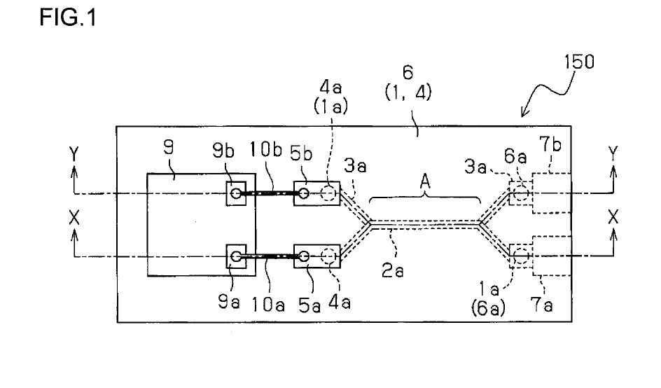

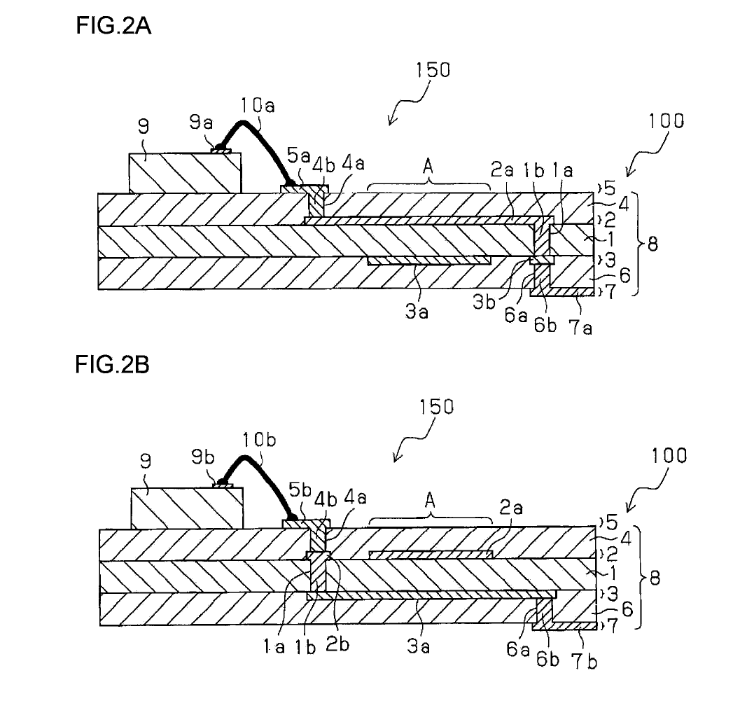

FIG. 1 is a plan view showing the configuration of a device mounting board and a semiconductor module according to the first embodiment of the present invention. FIG. 2A is a sectional view of the device mounting board and the semiconductor module taken along the line X-X of FIG. 1. FIG. 2B is a sectional view of the device mounting board and the semiconductor module taken along the line Y-Y of FIG. 1.

The device mounting board 100 of the first embodiment includes a wiring layer 8, signal wires 2a and 3a, a pair of pad electrodes 5a and 5b, a pair of pad electrodes 7a and 7b, and conductor parts 1b, 4b, and 6b. The wiring layer 8 has a plurality of conductive layers 2, 3, 5, and 7, and a plurality of insulating layers 1, 4, and 6 which are laminated alternately. The opposing signal wires 2a and 3a are formed on the conductive layers 2 and 3 and arranged in parallel with each other. The pad electrodes 5a and 5b are formed on the conductive layer 5 located at the top of the wiring layer 8. The pad electrodes 7a and 7b are formed on the conductive layer 7 located at the bottom of the wiring layer 8. The conductor parts 1b, 4b, and 6b are arranged through the respective insulating layers and establish electrical connection between the top and bottom conductive layers. A semiconductor module 150 according to the first embodiment is composed of the device mounting board 100, a circuit device 9, and a pair of signal electrodes 9a and 9b formed on this circuit device 9. The circuit device 9 is mounted on one of the main surfaces, or the top, of the wiring layer 8 of the device mounting board 100. The signal electrodes 9a and 9b are connected with the pair of pad electrodes 5a and 5b through conductive members 10a and 10b. Consequently, in the device mounting board 100 and the semiconductor module 150 including same, a line that extends from the pad electrode 5a to the pad electrode 7a through the signal wire 2a and a line that extends from the pad electrode 5b to the pad electrode 7b through the signal wire 3a constitute a pair of differential transmission lines.

The insulating layer 1 is interposed between the conductive layer 2 and the conductive layer 3. The insulating layer 1 electrically insulates the conductive layer 2 and the conductive layer 3 from each other. The insulating layer 1 is made of a film composed mainly of epoxy resin, with a thickness of approximately 80 μm, for example. In this instance, the insulating layer 1 composed mainly of epoxy resin may be a type of film that has glass woven fibers impregnated with resin included therein. The insulating layer 1 may alternatively be a film having a filler of approximately 2 μm to 10 μm in diameter added thereto. Examples of this filler include alumina (Al₂O₃), silica (SiO₂), aluminum nitride (AlN), silicon nitride (SiN), and boron nitride (BN). The suitable filling ratio of this filler is approximately 30% to 80% by weight.

The conductive layer 2 and the conductive layer 3 are formed on the top and bottom surfaces of the insulating layer 1, respectively. The conductive layers 2 and 3 are made of metal such as copper (Cu) or aluminum (Al), and have a thickness of approximately 20 μm, for example. The conductive layer 2 is formed in a predetermined wiring pattern which includes the signal wire 2a and a via land 2b. The conductive layer 3 is formed in a predetermined wiring pattern which includes the signal wire 3a and a via land 3b. In this instance, the signal wire 2a and the opposing signal wire 3a are arranged in a predetermined area A in parallel with each other, thereby constituting a pair of signal wires for transmitting differential signals.

The insulating layer 1 located between the conductive layers 2 and 3 has connect holes 1a passing from its top to bottom, and the conductor parts 1b made of copper or the like are formed in the connection holes 1a. These conductor parts 1b are arranged in predetermined positions and establish electrical connection between the conductive layers 2 and 3 formed on the top and bottom surfaces of the insulating layer 1.

The insulating layer 4 is formed so as to cover the conductive layer 2 located on top of the insulating layer 1. The insulating layer 4 electrically insulates the conductive layer 2 and the conductive layer 5 from each other. The insulating layer 4 is made of a material having the same composition as that of the insulating layer 1, and has a thickness of approximately 60 μm, for example.

The insulating layer 5 is formed on top of the insulating layer 4. The insulating layer 5 is made of the same metal as the conductive layers 2 and 3 are, and has a thickness of approximately 20 μm, for example. The conductive layer 5 is formed in a predetermined wiring pattern which includes the pair of pad electrodes 5a and 5b and other wiring parts (not shown). This pair of pad electrodes 5a and 5b are electrically connected with the pair of signal electrodes 9a and 9b of the circuit device 9 through the conductive members 10a and 10b.

The insulating layer 4 between the conductive layers 2 and 5 has connection holes 4a passing from its top to bottom, and the conductor parts 4b made of copper or the like are formed in the connection holes 4a. These conductor parts 4b are arranged in predetermined positions and establish electrical connection between the conductive layers 2 and 5 formed on the top and bottom surfaces of the insulating layer 4.

The insulating layer 6 is formed so as to cover the conductive layer 3 located on the bottom of the insulating layer 1. The insulating layer 6 electrically insulates the conductive layer 3 and the conductive layer 7 from each other. The insulating layer 6 is made of a material having the same composition as that of the insulating layer 1, and has a thickness of approximately 60 μm, for example.

The insulating layer 7 is formed on the bottom of the insulating layer 6. The insulating layer 7 is made of the same metal as the conductive layers 2 and 3, and has a thickness of approximately 20 μm, for example. The conductive layer 7 is formed in a predetermined wiring pattern which includes the pair of pad electrodes 7a and 7b and other wiring parts (not shown). In this instance, this pair of pad electrodes 7a and 7b functions as external lead electrodes for transmitting signals from the circuit device 9 to an exterior location.

The insulating layer 6 located between the conductive layers 3 and 7 has connection holes 6a passing from its top to bottom, and the conductor parts 6b made of copper or the like are formed in the connection holes 6a. These conductor parts 6b are arranged in predetermined positions, and establish electrical connection between the conductive layers 3 and 7 formed on the top and bottom surfaces of the insulating layer 6.

The wiring layer 8 is formed to constitute a four-layer structure which includes the conductive layers 2, 3, 5, and 7, and the insulating layers 1, 4, and 6 described above.

The circuit device 9 is a semiconductor device such as an IC chip or an LSI chip.

An LSI chip having a pair of signal electrodes 9a and 9b on its top is employed in this instance. The circuit device 9 is mounted on a predetermined area of the insulating layer 4 via an adhesive layer (not shown).

The conductive members 10a and 10b may be made of gold wires or the like, and electrically connect the pad electrodes 5a and 5b of the conductive layer 5 to the signal electrodes 9a and 9b of the circuit device 9 respectively by wire bonding. It should be appreciated that a sealing resin layer (not shown) made of epoxy resin may also be formed to cover the circuit device 9 so that the circuit device 9 arranged on the wiring layer 8 (insulating layer 4) is protected from external influences.

The device mounting board 100 according to the present embodiment is configured so that the sum of the lengths of the conductor part 4b for connecting the pad electrode 5a and the signal wire 2a to each other and the conductor parts 1b and 6b for connecting the signal wire 2a and the pad electrode 7a to each other is equal to the sum of the lengths of the conductor parts 1b and 4b used for connecting the pad electrode 5b and the signal wire 3a to each other and the conductor part 6b used for connecting the signal wire 3a and the pad electrode 7b to each other. The device mounting board 100 according to the present embodiment is also configured so that the length of wiring of the conductive layer 2 on which the signal wire 2a is formed, where the length of the signal wire 2a is included, is equal to the length of wiring of the conductive layer 3 on which the signal wire 3a is formed, where the length of the signal wire 3a is also included.

The device mounting board and the semiconductor module including same according to the present embodiment described above provide the following effects.
(1) The opposing signal wires 2a and 3a can be laminated and arranged inside the wiring layer 8 in parallel with each other so that the two lines passing through these signal wires 2a and 3a between the pad electrodes 5a and 5b and the pad electrodes 7a and 7b of the device mounting board constitute a pair of differential transmission lines of equal lengths. In this instance, any difference between the line length from the pad electrode 5a to the signal wire 2a and the line length from the pad electrode 5b to the signal wire 3a (corresponding to the depth of the conductor parts 1b) is compensated for by the difference between the line length from the signal wire 2a to the pad electrode 7a and the line length from the signal wire 3a to the pad electrode 7b. This compensation can suppress a mismatch in the differential impedance, so that the device mounting board can transmit predetermined signals accurately and operate the circuit device mounted thereon properly.
(2) Since the opposing signal wires 2a and 3b are laminated and arranged in parallel with each other, it is possible to reduce the area occupied by the signal wires in comparison to the cases where the signal wires are arranged in parallel within an identical plane. This makes it possible to miniaturize a device mounting board having such signal wires.
(3) The pair of signal electrodes 9a and 9b of the circuit device 9 are electrically connected to the pair of pad electrodes 5a and 5b, respectively, while the pair of pad electrodes 7a and 7b are used as external lead electrodes for transmitting signals of the circuit device 9 to an exterior location. It is therefore possible to transmit predetermined signals from the circuit device 9 mounted on the device mounting board to an exterior location accurately at high speed.

The foregoing embodiment has dealt with the wiring layer 8 of a four-layer structure. However, the present invention is not limited thereto. For example, the present invention may also be applied to a wiring layer of a double-layer structure or of a structure with five or more layers. In such cases, the same effects can also be obtained by forming a pair of opposing signal wires on different respective conductive layers in the wiring layer in parallel with each other, and connecting a pair of pad electrodes formed on one of the main surfaces of the wiring layer to a pair of pad electrodes formed on the other main surface of the wiring layer through conductor parts that are formed vertically through the conductive layers of the device mounting board.

The foregoing embodiment has dealt with a device mounting board that has the circuit device 9 mounted thereon and a semiconductor module. However, the present invention is not limited thereto. For example, the device mounting board may have no circuit device 9 mounted thereon.

The foregoing embodiment has dealt with the case where the pair of pad electrodes 7a and 7b of the device mounting board are used as external lead electrodes. However, the present invention is also not limited thereto. For example, another circuit device may be mounted on the bottom of the device mounting board so that a pair of signal electrodes of this circuit device are connected to the pair of pad electrodes 7a and 7b of the device mounting board, respectively. This makes it possible to transmit predetermined signals between the circuit device 9 located on top of the device mounting board and the circuit device located on the bottom accurately at high speed. In addition to this, when the circuit device 9 located on top of the device mounting board and the circuit device located on the bottom are configured in an overlapping arrangement, it is possible to further miniaturize the device mounting board. Such embodiments will now be detailed.

### Second Embodiment

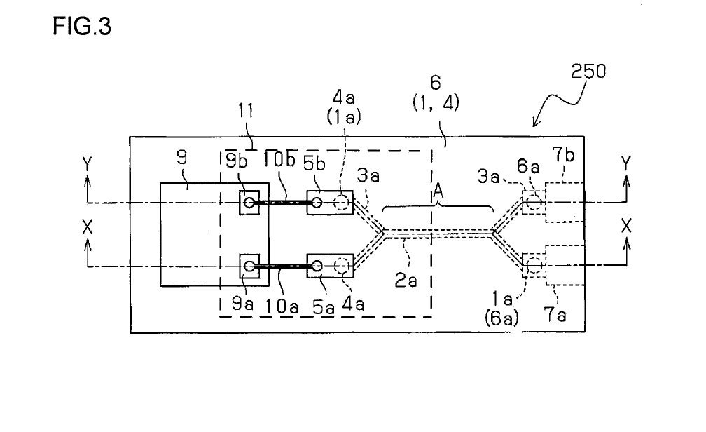

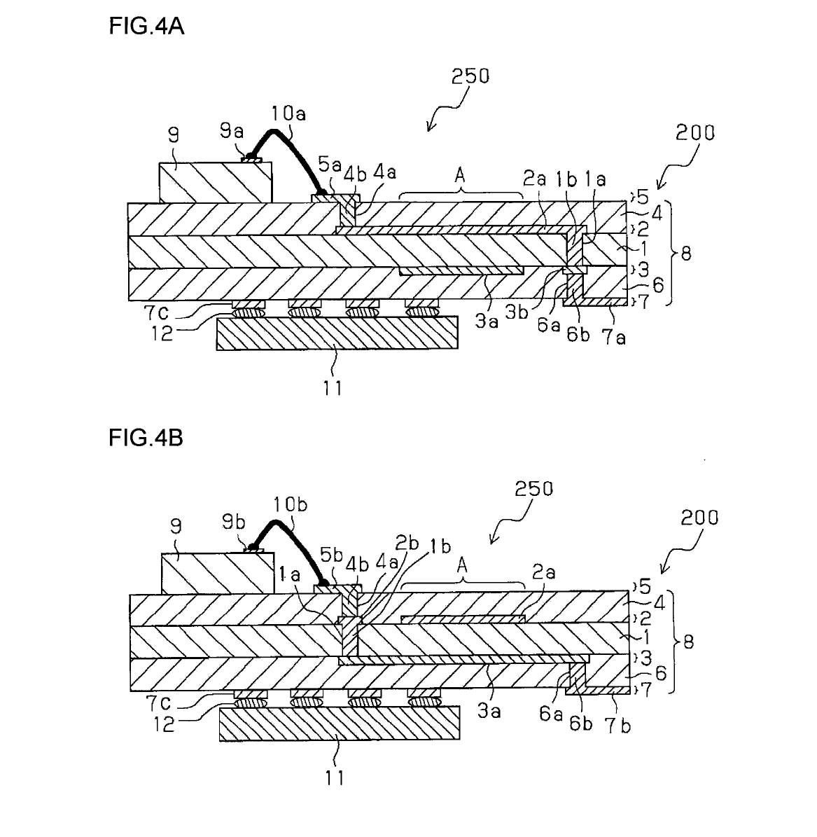

FIG. 3 is a plan view showing the configuration of a device mounting board and a semiconductor module according to the second embodiment of the present invention. FIG. 4A is a sectional view of the device mounting board and the semiconductor module taken along the line X-X of FIG. 3. FIG. 4B is a sectional view of the device mounting board and the semiconductor module taken along the line Y-Y of FIG. 3.

A semiconductor module 250 has a plurality of pad electrodes 7c formed on the conductive layer 7 at the bottom of the wiring layer 8 of a device mounting board 200. A circuit device 11 according to the present embodiment is an IC chip of BGA type, having a grid array of external input and output pads (not shown) on the bottom of its flat package. These pads and the pad electrodes 7c are connected via solder balls 12. In the semiconductor module 250 shown in FIGS. 3 to 4B, a line that extends from the pad electrode 5a to the pad electrode 7a through the signal wire 2a and a line that extends from the pad electrode 5b to the pad electrode 7b through the signal wire 3a constitute a pair of differential transmission lines of equal lengths. It should be appreciated that the pad electrodes of the circuit device 9 and those of the circuit device 11 may be connected to each other with a pair of differential transmission lines of equal length.

### Third Embodiment

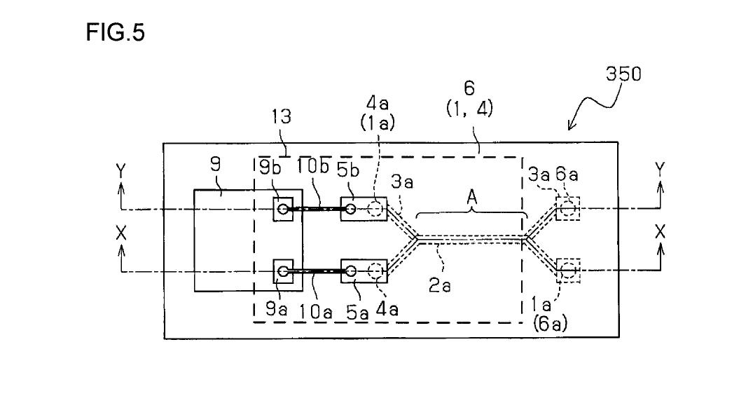

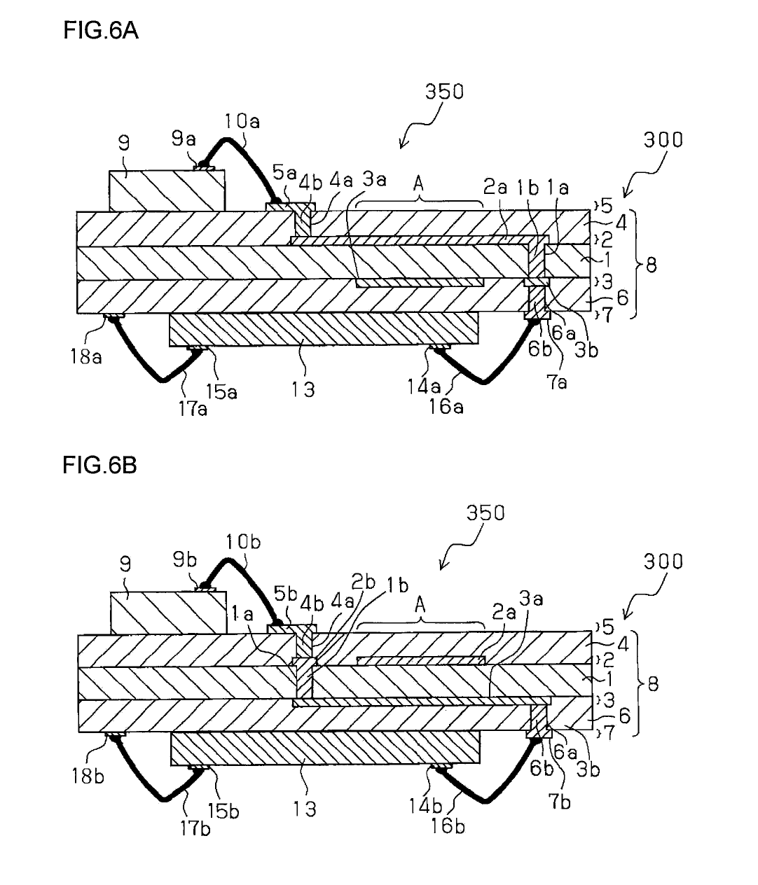

FIG. 5 is a plan view showing the configuration of a device mounting board according to a third embodiment of the present invention. FIG. 6A is a sectional view of the device mounting board taken along the line X-X of FIG. 5. FIG. 6B is a sectional view of the device mounting board taken along the line Y-Y of FIG. 5.

Aside from the circuit device 9 of the semiconductor module 150 according to the first embodiment, a semiconductor module 350 according to the third embodiment also has a circuit device 13 which is mounted on the side opposite to where the circuit device 9 is mounted. It should be appreciated that the device mounting board 300 according to the present embodiment is substantially the same as the device mounting board 100 according to the first embodiment. Identical components will thus be designated by like reference numerals, and a description thereof will be omitted as appropriate.

The circuit device 13 is a semiconductor chip such as an IC chip or an LSI chip.

In the present embodiment, an LSI chip having a plurality of pairs of signal electrodes 14a, 14b, 15a, and 15b at the bottom is employed as the circuit device 13. The circuit device 13 is mounted on a predetermined area of the insulating layer 6 via an adhesive layer (not shown).

Conductive members 16a and 16b may be made of gold wires or the like, and electrically connect the pad electrodes 7a and 7b of the conductive layer 7 to the signal electrodes 14a and 14b of the circuit device 13 respectively by wire bonding. Conductive members 17a and 17b may also be made of gold wires or the like, and electrically connect pad electrodes 18a and 18b of the conductive layer 7 to the signal electrodes 15a and 15b of the circuit device 13 respectively by wire bonding. It should be appreciated that a sealing resin layer (not shown) made of epoxy resin may also be formed to cover the circuit device 13 so that the circuit device 13 arranged on the wiring layer 8 (insulating layer 6) is protected from external influences.

### Fourth Embodiment

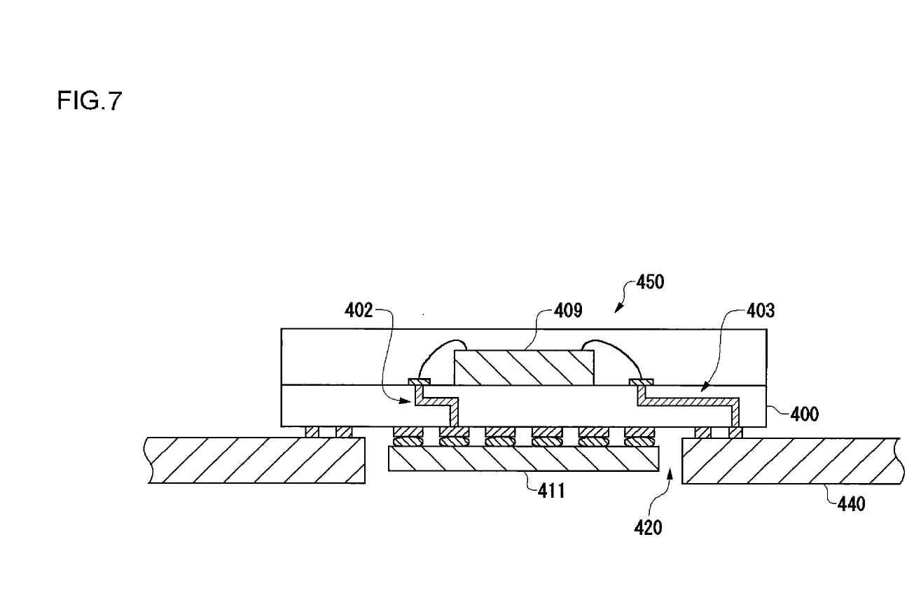

The present embodiment will deal with a method of mounting the semiconductor modules described in the foregoing embodiments onto a motherboard for installation. FIG. 7 is a schematic diagram showing how a semiconductor module is mounted on the motherboard according to the fourth embodiment. The motherboard 440 is an electronic circuit board that is configured so that a plurality of components for constituting an electronic apparatus can be mounted thereon. The motherboard 440 according to the present embodiment has a through hole 420 for precluding interference with a circuit device 411 that is formed on one side of the device mounting board 400 of a semiconductor module 450 to be mounted thereon.

The device mounting board 400 of the semiconductor module 450 has a pair of differential transmission lines 402 of mutually equal lengths for establishing electrical connection between a circuit device 409 and the circuit device 411, and a pair of differential transmission lines 403 of mutually equal lengths for establishing electrical connection between the circuit device 409 and the motherboard 440. FIG. 7 shows the device transmission lines 402 and 403 each with a single line for convenience, however, it should be appreciated that the device transmission lines are made of respective pairs of wires as is the case with the device mounting boards described in the foregoing embodiments.

### Fifth Embodiment

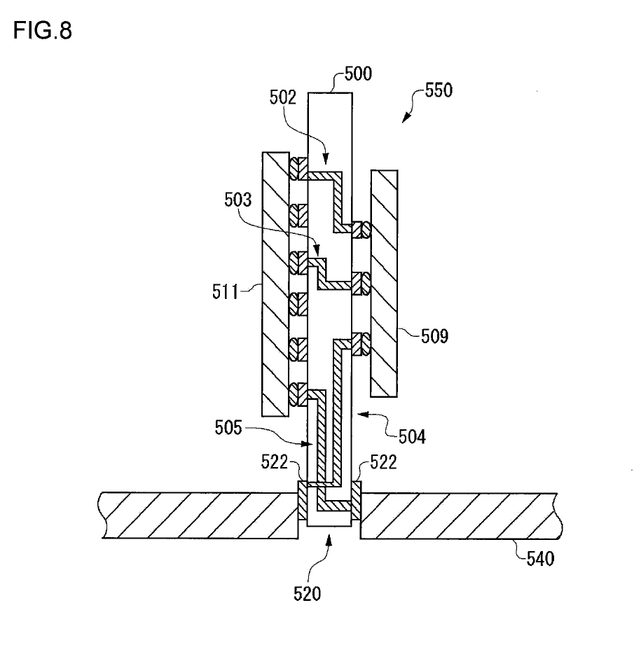

The present embodiment will deal with a method of mounting the semiconductor modules described in the foregoing embodiments vertically onto a motherboard. FIG. 8 is a schematic diagram showing how a semiconductor module is mounted on the motherboard according to the fifth embodiment. The motherboard 540 according to the present embodiment has an insertion slot 520 which is configured so that an end of a semiconductor module 550 to be mounted thereon is inserted and fixed thereto. When the semiconductor module 550 is inserted into the insertion slot 520, its external connection terminals 522 formed on its extremity come into contact with and are fixed by not-shown electrodes formed on the mother board 540.

A device mounting board 500 of the semiconductor module 550 has: two pairs of differential transmission lines 502 and 503 of mutually equal lengths for establishing electrical connection between a circuit device 509 and a circuit device 511; a pair of differential transmission lines 504 of mutually equal lengths for establishing electrical connection between the circuit device 509 and the motherboard 540; and a pair of differential transmission lines 505 of mutually equal lengths for establishing electrical connection between the circuit device 511 and the motherboard 540. FIG. 8 shows the device transmission lines 502, 503, 504, and 505 each with a single line for convenience, however, it should be appreciated that device transmission lines are made of respective pairs of wires as is the case with the device mounting boards described in the foregoing embodiments.

Up to this point, the present invention has been described with reference to the foregoing embodiments. Nevertheless, the present invention is not limited to any of the foregoing embodiments, and arbitrary combinations or substitutions of the constituting elements in the foregoing embodiments may also be covered by the present invention. Various modifications including design changes may also be made to the embodiments based on the knowledge of those who skilled in the art. All such modified embodiments are also intended to fall within the scope of the present invention.

What is claimed is:

1. A device mounting board comprising:
a wiring layer having a plurality of conductive layers and insulating layers laminated alternately;
a pair of first electrodes formed on one main surface of the wiring layer;
opposing signal wires formed on different conductive layers in the wiring layer being arranged in parallel with each other;
a pair of second electrodes formed on the other main surface of the wiring layer; and
conductor parts which are formed through the insulating layers and respectively establish electrical connection between the first electrodes and the signal wires and between the signal wires and the second electrodes, wherein
a first line extending from one of the first electrodes to one of the second electrodes and a second line extending from the other first electrode to the other second electrode constitute a pair of differential transmission lines of equal lengths.

2. The device mounting board according to claim 1, wherein:
the conductor parts on the first line are formed in the respective insulating layers one by one from the one main surface to the other main surface; and
the conductor parts on the second line are formed in the respective insulating layers one by one from the one main surface to the other main surface.

3. A device mounting board comprising:
a wiring layer having a plurality of conductive layers and insulating layers laminated alternately;
a pair of first electrodes formed on one main surface of the wiring layer;
a pair of signal wires formed on different conductive layers in the wiring layer, being opposed in parallel with each other;
a pair of second electrodes formed on the other main surface of the wiring layer;
a first conductive part which is formed through any of the insulating layers and establishes electrical connection between one of the pair of first electrodes and one of the pair of signal wires;
a second conductive part which is formed through any of the insulating layers and establishes electrical connection between the one of the pair of signal wires and one of the pair of second electrodes;
a third conductive part which is formed through any of the insulating layers and establishes electrical connection between the other of the pair of first electrodes and the other of the pair of signal wires; and
a fourth conductive part which is formed through any of the insulating layers and establishes electrical connection between the other of the pair of signal wires and the other of the pair of second electrodes, wherein
the length of wiring of the conductive layer on which the one of the pair of signal wires is formed, including that of the one of the pair of signal wires, is equal to the length of wiring of the conductive layer on which the other of the pair of signal wires is formed, including that of the other of the pair of signal wires,
the sum of the lengths of the first conductor part and the second conductor part in a direction perpendicular to the main surfaces of the wiring layer is equal to the sum of the lengths of the third conductor part and the fourth conductor part in the direction perpendicular to the main surfaces of the wiring layer, and
a first line extending from the one of the first electrodes to the one of the second electrodes and a second line extending from the other of the first electrodes to the other of the second electrodes constitute a pair of differential transmission lines of equal lengths

4. A semiconductor module comprising:
the device mounting board according to claim 1; and
a circuit device arranged on the one of the main surfaces of the wiring layer of the device mounting board, wherein
the pair of first electrodes are electrically connected with a pair of signal electrodes of the circuit device, respectively, and the pair of second electrodes function as external lead electrodes.

5. A semiconductor module comprising:
the device mounting board according to claim 1;
a first circuit device arranged on the one main surface of the wiring layer of the device mounting board; and
a second circuit device arranged on the other main surface of the wiring layer of the device mounting board, wherein
the pair of first electrodes are electrically connected with a pair of signal electrodes of the first circuit device, respectively, and
the pair of second electrodes are electrically connected with a pair of signal electrodes of the second circuit device, respectively.

6. A semiconductor module comprising:
the device mounting board according to claim 2; and
a circuit device arranged on the one main surface of the wiring layer of the device mounting board, wherein
the pair of first electrodes are electrically connected with a pair of signal electrodes of the circuit device, respectively, and the pair of second electrodes function as external lead electrodes.

7. A semiconductor module comprising:
the device mounting board according to claim 2;
a first circuit device arranged on the one main surface of the wiring layer of the device mounting board; and
a second circuit device arranged on the other main surface of the wiring layer of the device mounting board, wherein
the pair of first electrodes are electrically connected with a pair of signal electrodes of the first circuit device, respectively, and
the pair of second electrodes are electrically connected with a pair of signal electrodes of the second circuit device, respectively.

8. A semiconductor module comprising:
the device mounting board according to claim 3; and
a circuit device arranged on the one main surface of the wiring layer of the device mounting board, wherein
the pair of first electrodes are electrically connected with a pair of signal electrodes of the circuit device, respectively, and the pair of second electrodes function as external lead electrodes.

9. A semiconductor module comprising:
the device mounting board according to claim 3;
a first circuit device arranged on the one main surface of the wiring layer of the device mounting board; and
a second circuit device arranged on the other main surface of the wiring layer of the device mounting board, wherein
the pair of first electrodes are electrically connected with a pair of signal electrodes of the first circuit device, respectively, and
the pair of second electrodes are electrically connected with a pair of signal electrodes of the second circuit device, respectively.
